(19) United States
(12) Patent Application Publication
(10) Pub. No.: US 2012/0003833 A1
(43) Pub. Date: Jan. 5, 2012

(54) METHODS FOR FORMING TUNGSTEN-CONTAINING LAYERS

(75) Inventors: AMIT KHANDELWAL, San Jose, CA (US); KAI WU, Palo Alto, CA (US); EMILY RENUART, Santa Clara, CA (US); JINQIU CHEN, San Jose, CA (US); AVGERINOS V. GELATOS, Redwood City, CA (US)

(73) Assignee: APPLIED MATERIALS, INC., Santa Clara, CA (US)

(21) Appl. No.: 13/172,339

(22) Filed: Jun. 29, 2011

Related U.S. Application Data
(60) Provisional application No. 61/360,894, filed on Jul. 1, 2010.

(51) Int. Cl. H01L 21/285

(52) U.S. Cl. 438/680; 257/E21.161

(57) ABSTRACT

Methods for forming tungsten-containing layers on substrates are provided herein. In some embodiments, a method for forming a tungsten-containing layer on a substrate disposed in a process chamber may include mixing hydrogen and a hydride to form a first process gas; introducing the first process gas to the process chamber; exposing the substrate in the process chamber to the first process gas for a first period of time to form a conditioned substrate surface; subsequently purging the process chamber of the first process gas; exposing the substrate to a second process gas comprising a tungsten precursor for a second period of time to form a tungsten-containing nucleation layer atop the conditioned substrate surface; and subsequently purging the process chamber of the second process gas.

### CROSS-REFERENCE TO RELATED APPLICATIONS

This application claims benefit of U.S. provisional patent application Ser. No. 61/360,894, filed Jul. 1, 2010, which is herein incorporated by reference.

### FIELD

Embodiments of the present invention generally relate to semiconductor substrate processing, and more particularly, to methods for forming tungsten-containing layers.

### BACKGROUND

In the field of semiconductor, flat-panel display, or other electronic device processing, vapor deposition processes have played an important role in depositing materials on substrates. As the geometries of electronic devices continue to shrink and the density of devices continue to increase, overall feature size has decreased and aspect ratio has increased. While conventional chemical vapor deposition (CVD) processes have proved successful, shrinking device geometries require an alternative deposition technique, such as atomic layer deposition (ALD).

A conventional ALD process involves sequentially exposing a substrate to chemical precursors and reactants. Typically, a chemical precursor is provided to a process chamber having a substrate, which is adsorbed onto the surfaces of the substrate. A reactant is then provided to the process chamber, which reacts with the chemical precursor, resulting in a deposition of material, for example, a tungsten (W) containing layer. ALD processes generally allow for improved coverage of surfaces within substrate features over a conventional CVD process.

A typical process consists of ALD based nucleation to achieve improved step coverage followed by a CVD based bulk fill process to achieve target thickness and resistivity. A combination of both processes may be performed within a single process chamber, wherein a nucleation layer is deposited via an ALD process to obtain good step coverage and low film impurities, followed by a bulk layer deposited via a CVD process for increased process throughput. However, because of the divergent temperatures required to perform the ALD and CVD processes, controlling the temperature of the substrate is difficult and further time consuming to alternate between the higher and lower temperatures, thereby undesirably decreasing process throughput.

Therefore, the inventors have provided an improved method of processing substrates using ALD.

### SUMMARY

Methods for forming tungsten-containing layers on substrates are provided herein. In some embodiments, a method for forming a tungsten-containing layer on a substrate disposed in a process chamber may include mixing hydrogen and a hydride to form a first process gas; introducing the first process gas to the process chamber; exposing the substrate in the process chamber to the first process gas for a first period of time to form a conditioned substrate surface; subsequently purging the process chamber of the first process gas; exposing the substrate to a second process gas comprising a tungsten precursor for a second period of time to form a tungsten-containing nucleation layer atop the conditioned substrate surface; and subsequently purging the process chamber of the second process gas.

In some embodiments, the inventive methods described herein may be embodied in a computer readable medium. The computer readable medium has instructions stored thereon that, when executed, cause a process chamber to perform a method of cooling a process chamber component in accordance with any of the methods described herein.

The above summary is provided to briefly discuss some aspects of the present invention and is not intended to be limiting of the scope of the invention. Other embodiments and variations of the invention are provided below in the detailed description.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a method for forming a tungsten-containing layer on a substrate in accordance with some embodiments of the present invention.

FIG. 2 depicts an apparatus suitable for processing semiconductor substrates in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention generally relate to methods of forming tungsten-containing layers on substrates via deposition processes. The inventive methods may advantageously increase productivity and efficiency of processing semiconductor substrates by providing an increased temperature process window, thereby increasing the deposition rate without sacrificing layer uniformity and integrity across the substrate.

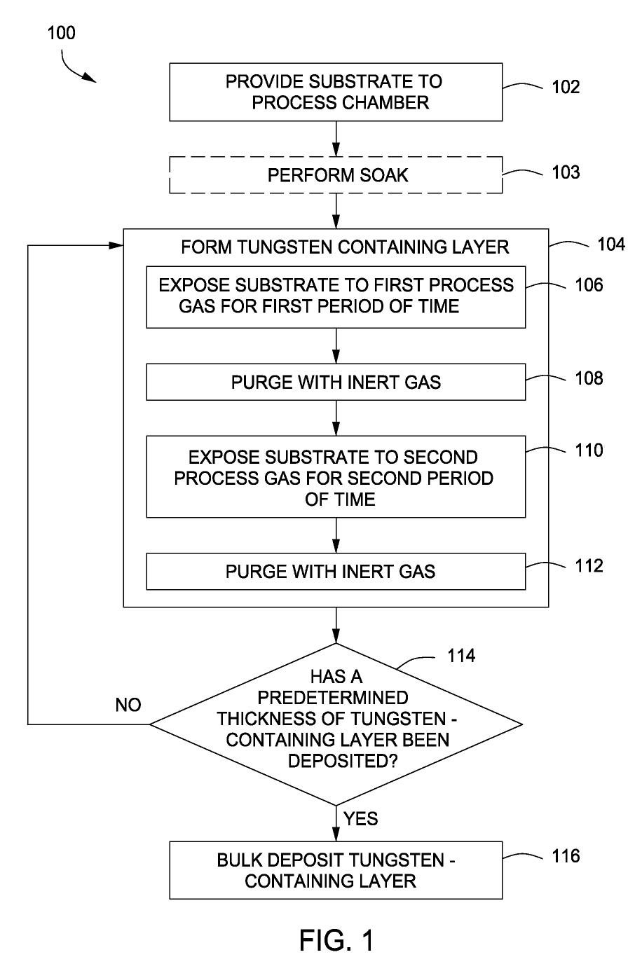

FIG. 1 depicts a method for forming a tungsten-containing layer on a substrate in accordance with some embodiments of the present invention. The method 100 generally begins at 102, where a substrate, having a surface upon which a tungsten-containing layer is to be formed is provided. As used herein, a “substrate surface” refers to any substrate surface upon which a layer may be formed. The substrate surface may have one or more features formed therein, one or more layers formed thereon, and combinations thereof. The substrate (or substrate surface) may be pretreated prior to the deposition of the tungsten-containing layer, for example, by polishing, etching, reduction, oxidation, halogenation, hydroxylation, annealing, baking, or the like.

The substrate may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. In some embodiments, one or more additional layers may be disposed on the substrate such that the tungsten-containing layer may be at least partially formed thereon. For example, in some embodiments, a layer comprising a metal, a nitride, an oxide, or the like, or combinations thereof may be disposed on the substrate and may have the tungsten containing layer formed upon such layer or layers.

In some embodiments, the substrate may be exposed to a soak process prior to beginning the cyclical deposition process to form a tungsten-containing layer on the substrate (as discussed below at 104), as shown in phantom at 103. In some embodiments, the soak process may comprise heating the substrate to a soak temperature followed by exposing the substrate to a soak gas. For example, in some embodiments, the substrate may be heated to a temperature of about 100 to about 600 degrees Celsius, or in some embodiments, about 200 to about 600 degrees Celsius, or in some embodiments about 300 to about 500 degrees Celsius, or in some embodiments about 350 to about 420 degrees Celsius, or in some embodiments about 375 to about 500 degrees Celsius.

In some embodiments, the soak gas may comprise a reducing gas comprising a hydrogen gas and/or a hydride compound, such as silane compounds (e.g., silane, disilane, trisilane, tetrasilane, chlorosilane, dichlorosilane, tetrachlorosilane, hexachlorodisilane, methylsilane, or the like), borane compounds (e.g., borane, diborane, triborane, tetraborane, pentaborane, alkylboranes, or the like), phosphine, ammonia, amine compounds, hydrogen, derivatives thereof, combinations thereof, or the like. When present, the reducing gas adsorbs and/or reacts to the substrate surface, to form a treated surface. The treated surface provides a quicker deposition process for an overall smooth and more uniform subsequently deposited layers.

In some embodiments, the reducing gas contains a hydrogen/hydride flow rate ratio of about 40:1 or greater, or in some embodiments, about 100:1 or greater, or in some embodiments, about 500:1 or greater, or in some embodiments, about 800:1 or greater, or in some embodiments, about 1,000:1 or greater. In some embodiments, the hydride compound (e.g., diborane) may have a flow rate of about 1 sccm to about 75 sccm, or in some embodiments, about 3 sccm to about 30 sccm, or in some embodiments, about 5 sccm to about 15 sccm. In some embodiments, the hydride compound may be within a carrier gas (e.g., hydrogen, nitrogen, argon, helium or the like), such that the mixture may have a flow rate within a range of about 50 sccm to about 500 sccm, or in some embodiments, about 75 sccm to about 400 sccm, or in some embodiments, about 100 sccm to about 300 sccm. In some embodiments, the hydrogen gas may be provided at a flow rate of about 1 slm to about 20 slm, or in some embodiments, from about 3 slm to about 15 slm, or in some embodiments, from about 5 slm to about 10 slm. The hydrogen/hydride flow rate ratio may be calculated by dividing the total hydrogen flow rate by the total hydride flow rate. The total hydrogen flow rate contains the sum of all sources of hydrogen including the flow rate of any hydrogen carrier gas and the flow rate of any independent hydrogen gas.

In some embodiments, the reducing gas may be mixed within the processing/deposition chamber or outside and may be coming from multiple sources. For example, in some embodiments, the substrate is exposed to the reducing gas which is formed by combining in the chamber a gas flow of a reducing or hydride compound and hydrogen mixture (e.g., 5% B₂H₆ in H₂) along with a gas flow of hydrogen gas. In another example, in some embodiments, the gas flow of the reducing or hydride compound and hydrogen mixture (e.g., 5% B₂H₆ in H₂) and the gas flow of hydrogen gas are combined prior to entering the chamber. Additional process parameters may be utilized to facilitate the soak process. For example, in some embodiments, the soak process may be performed while maintaining a pressure in the process chamber of about 1 Torr to about 150 Torr, or in some embodiments, from about 1 Torr to about 100 Torr, or in some embodiments, from about 10 Torr to about 50 Torr, or in some embodiments, from about 20 Torr to about 40 Torr, or in some embodiments, about 5 Torr to about 20 Torr. In some embodiments, the soak process may be performed for a time period within of about 1 second to about 90 seconds, or in some embodiments, less than about 60 seconds, or in some embodiments, less than about 30 seconds, or in some embodiments, less than about 10 seconds.

Next, at 104, a tungsten-containing layer is formed on the substrate. The tungsten-containing layer may be formed via a cyclical deposition process, such as atomic layer deposition (ALD), or the like. In some embodiments, the forming of a tungsten-containing layer via a cyclical deposition process may generally comprise exposing the substrate to two or more process gases sequentially. In some embodiments, each process gases may be separated by a time delay/pause to allow the components of the process gases to adhere and/or react on the substrate surface. Alternatively, or in combination, in some embodiments, a purge may be performed before and/or after the exposure of the substrate to the process gases, wherein an inert gas is used to perform the purge. For example, a first process gas may be provided to the process chamber followed by a purge with an inert gas. Next, a second process gas may be provided to the process chamber followed by a purge with an inert gas. In some embodiments, the inert gas may be continuously provided to the process chamber and the first process gas may be dosed or pulsed into the process chamber followed by a dose or pulse of the second process gas into the process chamber. In such embodiments, a delay or pause may occur between the dose of the first process gas and the second process gas, allowing the continuous flow of inert gas to purge the process chamber between doses of the process gases. In any of the embodiments described above, the sequences may be repeated until a desired layer thickness is formed on the substrate surface.

A “pulse” or “dose” as used herein is intended to refer to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds, for example, the process gases described below.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

In some embodiments, the process of forming the tungsten-containing layer at 104 may begin by exposing the substrate to a first process gas comprising hydrogen (H₂) and a hydride for a first period of time, as shown at 106.

In some embodiments, the first process gas may be provided in one or more pulses at a flow rate of about 5 to about 2000 sccm for a first time period of up to about 5 seconds. In some embodiments, the first process gas is not pulsed and provided at a constant flow rate of about 5 to about 2000 sccm for a first time period of about 0.1 to about 5 seconds.

The hydride adsorbs and/or reacts with the substrate surface to form a conditioned surface, allowing for a uniform tungsten-containing layer to be formed. In some embodiments, the hydride may comprise silane (SiₓH_{y}) compounds (e.g., silane (SiH₄), disilane (Si2H6), trisilane (Si₃H₈), chlorosilane, dichlorosilane (H₂SiCl₂), or the like), borane (BₓH_{y}) compounds (e.g., diborane (B₂H₆), triborane (B₃H₈), pentaborane (B₅H₉), or the like), phosphine (PH₃), derivatives thereof, combinations thereof, or the like. In addition, in some embodiments, the hydride may be diluted in a dilutant gas, for example an inert gas, such as argon (Ar), helium (He), nitrogen (N₂), hydrogen (H₂), or the like. For example, in such embodiments, the hydride may be provided in a mixture of about 5% hydride to about 95% dilutant gas by volume. In some embodiments, for example where the hydride comprises diborane, the flow rate of the hydride may be about 1 to about 75 sccm.

Alternatively, in some embodiments, for example where the hydride comprises disilane, the flow rate of the hydride may be about 1 to about 1500 sccm.

In some embodiments, the flow rate ratio of hydrogen to the hydride may be about 2000:1 to about 1:1, or in some embodiments, from about 400:1 to about 10:1, or in some embodiments, about 20:1. By providing the aforementioned ratios of hydrogen to hydride, the presence of excess hydrogen may reduce or reverse decomposition of the hydride via thermal and/or chemical mechanisms. For example, the hydrogen may reduce the effective temperature of the substrate (i.e., the effective substrate temperature), thereby suppressing the decomposition of the hydride. By reducing the effective substrate temperature, a wider process temperature window for the deposition process may be provided, thereby allowing for an increased rate of deposition of the CVD bulk tungsten layer, as discussed below. Accordingly, in some embodiments, the ratio of hydrogen to the hydride may be adjusted to control the effective substrate temperature. In addition, in some embodiments, for example where the hydride comprises diborane, the hydrogen may reduce or reverse the hydride decomposition reaction. In such embodiments, the ratio of hydrogen to the hydride may be adjusted to control the decomposition of the hydride.

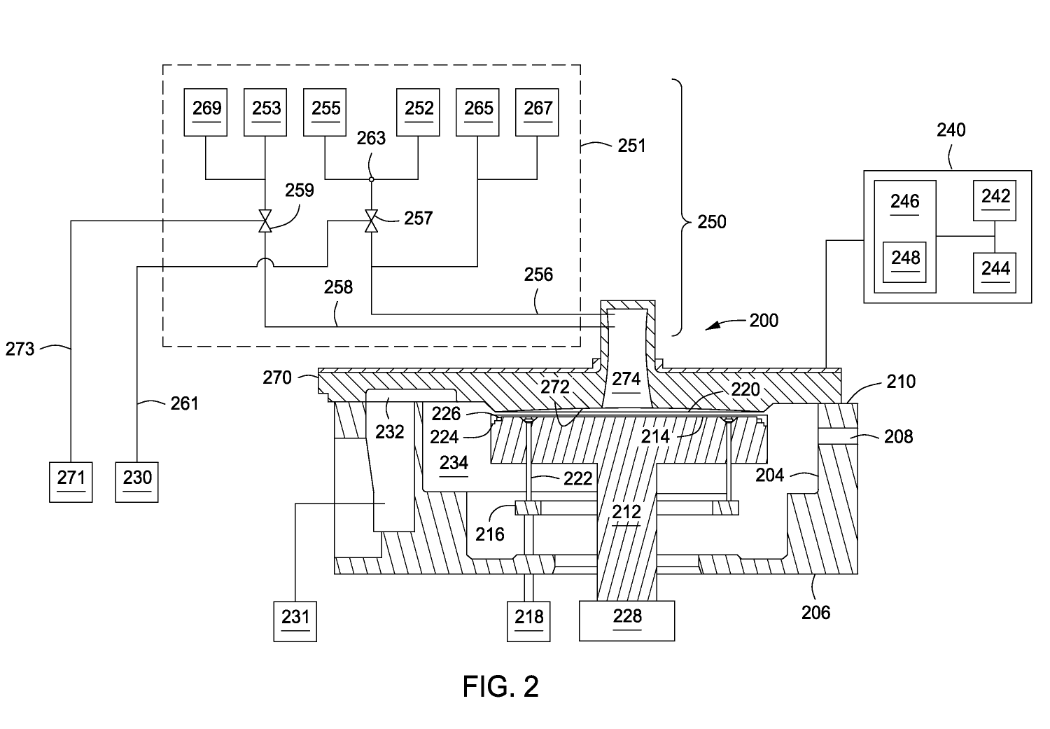

In some embodiments, the components of the first process gas (i.e., the hydrogen and hydride) may be mixed prior to providing the first process gas to the process chamber. In such embodiments, a gas panel may be configured to mix the first process gas components upstream of a valve configured to allow the first process gas to be flowed into the process chamber or diverted away from the process chamber (for example, such as gas panel 251 of process chamber 200, described below with respect to FIG. 2).

By mixing the first process gas components prior to providing the first process gas to the process chamber and flowing or diverting the hydrogen and hydride simultaneously, the first process gas is provided in a more homogenous mixture. Moreover, the presence of excess hydrogen in the process chamber is reduced, thereby preventing the hydrogen from reacting with the tungsten-containing precursor in subsequent process steps (described below), and thus providing a more uniform nucleation step coverage. For example, the inventors have discovered that excess hydrogen in the process chamber, such as may exist when hydrogen is used as a purge gas or is otherwise continuously provided to the process chamber, may undesirably react with the tungsten precursor (e.g., tungsten hexafluoride (WF₆), discussed below), resulting in decreased step coverage of deposited layers. Thus, embodiments of the present invention may further improve step coverage by reducing the presence of excess hydrogen in the chamber and preventing a reaction between the hydrogen gas and the tungsten precursor by providing and diverting the flow of hydrogen along with the hydride.

The first period of time may be any suitable amount of time necessary to allow the hydride to adsorb into a top layer of the substrate to form a conditioned layer for a subsequent deposition of the tungsten-containing layer, for example, as described below, thereby allowing for a uniform deposition. For example, the first process gas may be flowed into the process chamber for a period of about 1 to about 90 seconds.

In some embodiments, an inert gas may additionally be provided to the process chamber at a constant flow, for example from about 1 to about 10000 sccm. The inert gas may be any inert gas, for example, such as argon, helium, neon, combinations thereof, or the like. By providing the inert gas, the effective substrate temperature may be further reduced, allowing for a wider process temperature window for the deposition process, thereby allowing for an increased rate of deposition of the tungsten-containing layer. In addition, by providing an inert gas with a higher thermal conductivity relative to other inert gases, for example, such as helium, a transfer of heat away from the substrate is increased, thereby effectuating a further reduction in the effective substrate temperature.

In addition to the foregoing, additional process parameters may be regulated while exposing the substrate to the first process gas. For example, in some embodiments, the process chamber may be maintained at a pressure of about 0.3 to about 90 Torr. In addition, in some embodiments, the temperature of the pedestal may be maintained at a temperature of about 250 degrees Celsius to about 500 degrees Celsius.

Next, at 108, the process chamber may be purged using an inert gas. The inert gas may be any inert gas, for example, such as argon, helium, neon, or the like. In some embodiments, the inert gas may be the same, or alternatively, may be different from the inert gas provided to the process chamber during the exposure of the substrate to the first process gas at 106. In embodiments where the inert gas is the same, the purge may be performed by diverting the first process gas from the process chamber, allowing the inert gas to flow through the process chamber, thereby purging the process chamber of any excess first process gas components or reaction byproducts. In some embodiments, the inert gas may be provided at the same flow rate used in conjunction with the first process gas, described above, or in some embodiments, the flow rate may be increased or decreased. For example, in some embodiments, the inert gas may be provided to the process chamber at a flow rate of about 0 to about 10000 sccm to purge the process chamber.

The flow of inert gas may facilitate removing any excess first process gas components and/or excess reaction byproducts from the process chamber to prevent unwanted gas phase reactions of the first and second process gases. For example, the flow of inert gas may remove excess hydrogen from the process chamber, thereby preventing a reaction between the hydrogen and tungsten precursor used in a subsequent deposition of the tungsten containing layer, such as described below with respect to 110.

Next, at 110, the substrate is exposed to a second process gas for a second period of time. In some embodiments, the second process gas comprises a tungsten precursor, for example, a halide based tungsten precursor or a metal-organic based tungsten precursor. For example, in some embodiments, the tungsten precursor may comprise tungsten hexafluoride (WF₆), tungsten hexachloride (WCl₆), tungsten carbonyl (W(CO)₆), bis(cyclopentadienyl) tungsten dichloride (CP₂WCl₂), mesitylene tungsten tricarbonyl (C₉H¹²W(CO)₃) or the like. The second process gas forms a tungsten-containing nucleation layer atop the conditioned substrate surfaces.

In some embodiments, the second process gas may be provided in one or more pulses at a flow rate of about 5 to about 2000 sccm for a second time period of up to about 5 seconds. In some embodiments, the second process gas is not pulsed and provided at a constant flow rate of between about 5 to about 2000 sccm for a second time period of between about 0.1 to about 5 seconds

The second period of time may be any suitable amount of time necessary to allow the tungsten precursor to form an adequate nucleation layer atop the substrate surfaces. For example, the second process gas may be flowed into the process chamber for a period of about 0.1 seconds to about 90 seconds.

In some embodiments, an inert gas may additionally be provided to the process chamber at a constant flow, for example from about 1 to about 1000 sccm. The inert gas may be any inert gas, for example, such as argon, helium, neon, combinations thereof, or the like. By providing the inert gas, the effective wafer temperature of the substrate may be further reduced, thereby allowing for a wider process temperature window for the deposition process. For example, in some embodiments, as the temperature of the substrate decreases, the deposition rate of the tungsten-containing layer may increase. In addition, by providing an inert gas with a higher thermal conductivity relative to other inert gases, for example, such as helium, a transfer of heat away from the substrate is increased, thereby effectuating a further reduction in the effective substrate temperature.

In addition to the foregoing, additional process parameters may be regulated while exposing the substrate to a second process gas. For example, in some embodiments, the process chamber may be maintained at a pressure of about 0.3 to about 90 Torr. In addition, in some embodiments, the temperature of the process chamber may be maintained at a temperature of about 250 degrees Celsius to about 500 degrees Celsius.

Next, at 112, process chamber may be purged using an inert gas. The inert gas may be any inert gas, for example, such as argon, helium, neon, or the like. In some embodiments, the inert gas may be the same, or alternatively, may be different from the inert gas provided to the process chamber during previous process steps. In embodiments where the inert gas is the same, the purge may be performed by diverting the second process gas from the process chamber, allowing the inert gas to flow through the process chamber, thereby purging the process chamber of any excess second process gas components or reaction byproducts. In some embodiments, the inert gas may be provided at the same flow rate used in conjunction with the second process gas, described above, or in some embodiments, the flow rate may be increased or decreased. For example, in some embodiments, the inert gas may be provided to the process chamber at a flow rate of about 0 to about 10,000 sccm to purge the process chamber.

The flow of inert gas may facilitate removing any excess second process gas components from the process chamber to prevent unwanted gas phase reactions of the first and second process gases. For example, the flow of inert gas may remove excess tungsten precursor from the process chamber, thereby preventing a reaction between the tungsten precursor and process gases used in subsequent process steps. For example, in embodiments where the process of forming a tungsten containing layer at 104 is repeated more than one time, the removal of excess tungsten precursor will prevent a reaction of the tungsten precursor with the hydrogen of the first process gas.

In addition to the foregoing, additional process parameters may be regulated while depositing the tungsten-containing layer to the desired thickness. For example, in some embodiments, the process chamber may be maintained at a pressure of about 0.3 to about 90 Torr. In addition, in some embodiments, the temperature of the process chamber may be maintained at a temperature of about 250 degrees Celsius to about 500 degrees Celsius.

Next, at 114, it is determined whether the tungsten-containing layer has achieved a predetermined thickness. If the predetermined thickness has not been achieved, the method 100 returns to 104 to continue forming the tungsten-containing layer until the predetermined, or desired, thickness is reached. Once the predetermined thickness has been reached, the method 100 proceeds to 116 where a bulk deposition process may be performed to deposit the remaining thickness of the tungsten-containing layer. In some embodiments, the bulk deposition process may be a CVD process. Upon completion of deposition of the tungsten-containing layer to a desired thickness, the method 100 generally ends and the substrate can proceed for any further processing.

In any of the above embodiments, each cycle consisting of exposing the substrate to a first process gas, purging with an inert gas, exposing the substrate to a second process gas, and purging with an inert gas may form a tungsten-containing layer having a thickness of about 0.1 to about 15 Å on the substrate. The sequence may be repeated until a desired total thickness of the tungsten-containing layer is achieved. For example, in some embodiments, the tungsten-containing layer may comprise a total thickness of about 2 to about 200 Å, or in some embodiments, about 50 Å. Accordingly, the deposition process may require up to about 2000 cycles to reach the desired thickness.

Upon forming the tungsten-containing layer to the desired thickness by the above ALD process, the method generally ends, and further processing may be performed on the substrate. For example, in some embodiments, a CVD process may be performed to bulk deposit the tungsten-containing layer to a target thickness. For example in some embodiments, the tungsten-containing layer may be deposited via CVD reaction of the tungsten precursor and hydrogen to form a total layer thickness of about 10 to about 10,000 Å, or in some embodiments, about 10 to about 100 Å, or in some embodiments, about 500 to about 5,000 Å.

In any of the above embodiments, the flow rates and/or durations of each pulse may be the same or may vary over the course of the total cycles required to form a particular tungsten-containing layer, thereby facilitating layers having either uniform or graded compositions.

FIG. 2 is a schematic cross-sectional view of an embodiment of an apparatus that may be used to perform embodiments of the present invention. The apparatus may be any suitable apparatus for processing substrates, for example, the GEMINI ALD chamber or the Centura ALD chamber, both available from Applied Materials, Inc., of Santa Clara, Calif.

The apparatus of FIG. 2 is generally a process chamber 200 having a chamber body 206 and a chamber lid 270 disposed on an upper surface 210 of the chamber body 206 to define an interior volume 234. A substrate support 212 disposed in the interior volume 234 supports the substrate 220 on a substrate receiving surface 214. The substrate support (or pedestal) 212 is mounted to a lift motor 228 to raise or lower the substrate support 212 and a substrate 220 disposed thereon. A lift plate 216 coupled to a lift motor 218 is mounted in the process chamber 200 and raises or lowers pins 222 movably disposed through the substrate support 212. The pins 222 raise or lower the substrate 220 over the surface of the substrate support 212. In some embodiments, the substrate support 212 includes a vacuum chuck, an electrostatic chuck, or a clamp ring for securing the substrate 220 to the substrate support 212. An opening 208 formed in a wall 204 of the chamber body 206 facilitates entry and egress of a substrate into and out of the process chamber 200.

The substrate support 212 is heated to increase the temperature of the substrate 220 disposed thereon. For example, the substrate support 212 may be heated using an embedded heating element, such as a resistive heater or may be heated using radiant heat, such as heating lamps disposed above the substrate support 212. A purge ring 224 is disposed on the substrate support 212 to define a purge channel 226 which provides a purge gas to a peripheral portion of the substrate 220 to prevent deposition thereon.

An exhaust system 231 is in communication with a pumping channel 232 to evacuate any undesirable gases from the process chamber 200. The exhaust system 231 also helps in maintaining a desired pressure or a desired pressure range inside the process chamber 200.

The gas delivery system 250 is coupled to the chamber body 206 to provide precursors, process gases, carrier gases and/or purge gases to the process chamber 200. The gas delivery system 250 may generally comprise a gas panel 251 having a plurality of gas sources (six shown) 252, 253, 255, 265, 267, 269 and a plurality of valves (two shown) 257, 259 coupled to one or more conduits (e.g., conduits 256, 258) to control a flow of gas from the gas panel 251 to the process chamber 200. In some embodiments, the plurality of gas sources 252, 253, 255, 265, 267, 269 may be configured such that each of the plurality of gas sources 252, 253, 255, 265, 267, 269 may provide a separate gas (e.g., a precursor, process gas, carrier gas, purge gas, etc.), for example, such as the gases described above with respect to FIG. 1.

For example, in embodiments where the gas delivery system 250 may be utilized to perform a method for forming a tungsten-containing layer as described above, a first gas source and second gas source (e.g., gas sources 252 and gas source 255) may provide hydrogen and a hydride, respectively, to form the first process gas. A third gas source and fourth gas source (e.g., gas source 265 and gas source 267) may be coupled to the first gas source and second gas source downstream of a valve 257 (described below) to provide an inert gas and hydrogen, respectively. A fifth gas source (e.g., gas source 253) may provide the second process gas comprising the tungsten precursor. A sixth gas source (e.g., gas source 269) may be coupled to the fifth gas source and provide an inert gas (e.g., argon (Ar), or the like).

In some embodiments, for example such as depicted in FIG. 2, the gas panel 251 may be configured to combine some of the gases provided by the plurality of gas sources 252, 253, 255, 265, 267, 269 prior to reaching the process chamber 200. In some embodiments, one or more valves 257, 259 may be disposed along the conduits 256, 261 to control the flow of gas provided by the plurality of gas sources 252, 253, 255, 265, 267, 269. The valves 257, 259 may be any type of valve, for example, a switching valve, high speed valve, stop valve, or the like, to facilitate pulsing the gas provided by the gas panel 251. In some embodiments, for example, as depicted in FIG. 2, the valves 257, 259 may be a two way valve, for example a diverter valve configured to divert the flow of gas away from the process chamber 200 via conduits 261, 273 coupled to an exhaust system 230, 271. The exhaust systems, 230, 231, and 271 may each be the same exhaust system or may be partially or completely separate systems to prevent reaction and/or deposition of materials within the exhaust system that may shorten the life or require maintenance and/or cleaning of the components of the exhaust system (e.g., pumps, conduits, valves, and the like). In such embodiments, the valves 257, 259 may be located in any position along the respective conduits 256, 258 suitable to selectively control one or more gases simultaneously. For example, the valve 257 (a first valve) may be disposed downstream of a junction 263 coupling the first gas source 252 and second gas source 255 to selectively provide the gases to the process chamber 200 via the conduit 256 or divert the gases to the exhaust system 230 via the conduit 261, as depicted in FIG. 2. In addition, in some embodiments, the valve 259 (a second valve) may be disposed downstream of the fifth gas source 253 to selectively provide the gases to the process chamber 200 via the conduit 258 or divert the gases to the exhaust system 271 via the conduit 273. In some embodiments, the sixth gas source 269 may be coupled to the fifth gas source 253 upstream of the valve 259 (as shown) or downstream of the valve 259 to allow gases provided by the sixth gas source 269 to be provided with the gases from the fifth gas source 253.

In some embodiments, one or more flow restrictors (not shown) may be disposed along the conduit 256 before and/or after the valves 257, 259. The inclusion of the one or more flow restrictors may reduce variations in pressure within the conduit 256 when the flow of gas is diverted to or from the process chamber, thereby delivering consistent quantities of the gases provided by the gas sources 252, 253, 255.

In some embodiments, for example, such as where a solid or liquid precursor is utilized, the gas delivery system 250 may also comprise one or more ampoules. In such embodiments, the one or more ampoules may be configured to allow the solid or liquid precursor to be contained and sublime into gaseous form for delivery into the process chamber 200.

Returning to FIG. 2, at least a portion of a bottom surface 272 of the chamber lid 270 may be tapered from an expanding channel 274 to a peripheral portion of the chamber lid 270. The expanding channel 274 improves velocity profile of gas flow from the expanding channel 274 across the surface of the substrate 220 (i.e., from the center of the substrate to the edge of the substrate). In some embodiments, the bottom surface 272 comprises one or more tapered surfaces, such as a straight surface, a concave surface, a convex surface, or combinations thereof. In some embodiments, the bottom surface 272 is tapered in the shape of a funnel. The expanding channel 274 is one exemplary embodiment of a gas inlet for delivering the sublimed precursor and carrier gas from the conduit 256 to the substrate 220. Other gas inlets are possible, for example, a funnel, a non-tapering channel, nozzles, showerheads, or the like.

A controller 240, such as a programmed personal computer, work station computer, or the like is coupled to the process chamber 200. Illustratively, the controller 240 comprises a central processing unit (CPU) 242, support circuitry 244, and a memory 246 containing associated control software 248. The controller 240 controls the operating conditions of processes performed in the process chamber, such as, for example, an ALD process as described above with respect to FIG. 1. For example, the controller 240 may be configured to control the flow of various precursor gases and purge gases from the gas delivery system 250 to the process chamber 200 during different stages of the deposition cycle.

While the foregoing is directed to embodiments of the present invention, other and further embodiments of the invention may be devised without departing from the basic scope thereof.

1. A method for forming a tungsten-containing layer on a substrate disposed in a process chamber, comprising:
(a) mixing hydrogen and a hydride to form a first process gas;
(b) introducing the first process gas to the process chamber;
(c) exposing the substrate in the process chamber to the first process gas for a first period of time to form a conditioned substrate surface;
(d) subsequently purging the process chamber of the first process gas;
(e) exposing the substrate to a second process gas comprising a tungsten precursor for a second period of time to form a tungsten-containing nucleation layer atop the conditioned substrate surface; and
(f) subsequently purging the process chamber of the second process gas.

2. The method of claim 1, wherein (b)-(f) is repeated until a desired thickness is achieved.

3. The method of claim 1, wherein an inert gas is continuously supplied to the process chamber while performing (b)-(f), the inert gas acting as a carrier gas when providing the first and the second process gases and as a purge gas when purging the process chamber.

4. The method of claim 1, wherein the first process gas is provided to the process chamber at a constant flow at a flow rate of about 1 to about 2000 sccm.

5. The method of claim 1, wherein the first process gas is provided to the process chamber in one or more pulses at a flow rate of about 1 to about 2000 sccm.

6. The method of claim 1, wherein the first period of time is about 0.1 to about 90 seconds.

7. The method of claim 1, wherein the hydride comprises at least one of silane (SiH₄), disilane (Si2H6), trisilane (Si₃H₈), chlorosilane, dichlorosilane (H₂SiCl₂), diborane (B₂H₆), triborane (B₃H₈), pentaborane (B₅H₉), phosphine (PH₃).

8. The method of claim 1, wherein the first process gas comprises a flow rate ratio of hydrogen to hydride of about 2000:1 to about 1:1.

9. The method of claim 8, wherein the flow rate ratio of hydrogen to the hydride is adjusted to control at least one of a decomposition of the hydride or an effective temperature of the substrate.

10. The method of claim 1, wherein the process chamber is maintained at pressure of about 0.3 to about 90 Torr while exposing the substrate to the first process gas.

11. The method of claim 1, wherein the second process gas is provided to the process chamber in a constant flow at a flow rate of about 5 to about 2,000 sccm.

12. The method of claim 1, wherein the second process gas is provided to the process chamber in one or more pulses at a flow rate of about 5 to about 2,000 sccm.

13. The method of claim 1, wherein the tungsten precursor comprises one of tungsten hexafluoride (WF₆), tungsten hexachloride (WCl₆), tungsten carbonyl (W(CO)₆), bis(cyclopentadienyl) tungsten dichloride (CP₂WCl₂), mesitylene tungsten tricarbonyl (C₉H₁₂W(CO)₃).

14. The method of claim 1, wherein the second period of time is about 0.1 to about 90 seconds.

15. The method of claim 1, wherein the process chamber is maintained at pressure of about 0.3 to about 90 Torr while exposing the substrate to the second process gas.

16. The method of claim 1, wherein the wherein the inert gas comprises argon (Ar), helium (He) or neon (Ne).

17. The method of claim 1, wherein the inert gas is provided at a flow rate of about 1 to about 10,000 sccm.

18. The method of claim 1, wherein the process chamber is maintained at a temperature of about 250 to about 500 degrees Celsius while exposing the substrate to the first process gas.

19. The method of claim 1, wherein the process chamber is maintained at a temperature of about 250 to about 500 degrees Celsius while exposing the substrate to the second process gas.

20. A computer readable medium having instructions store thereon that, when executed by a controller, causes a process chamber to perform a method for forming a tungsten-containing layer on a substrate disposed in a process chamber, the method comprising:
(a) mixing hydrogen and a hydride to form a first process gas;
(b) introducing the first process gas to the process chamber;
(c) exposing the substrate in the process chamber to the first process gas for a first period of time to form a conditioned substrate surface;
(d) subsequently purging the process chamber of the first process gas;
(e) exposing the substrate to a second process gas comprising a tungsten precursor for a second period of time to form a tungsten-containing nucleation layer atop the conditioned substrate surface; and
(f) subsequently purging the process chamber of the second process gas.
